(19) United States
(12) Patent Application Publication
(10) Pub. No.: US 2025/0052831 A1
(43) Pub. Date: Feb. 13, 2025

(54) METHOD FOR MONITORING THE STATE OF HEALTH OF AN EXPLOSIVE CELL BATTERY AND DEVICE IMPLEMENTING THIS METHOD

(71) Applicant: SAFRAN ELECTRICAL & POWER, BLAGNAC (FR)

(72) Inventor: Romain SCHMITTER, MOISSY CRAMAYEL (FR)

(21) Appl. No.: 18/719,639

(22) PCT Filed: Dec. 1, 2022
(86) PCT No.: PCT/FR2022/052211

§ 371 Date: Jun. 13, 2024

(30) Foreign Application Priority Data
Dec. 14, 2021 (FR) FR2113505

(51) Int. Cl. G01R 31/392; H01M 10/42; H01M 10/48

(52) U.S. Cl. CPC G01R 31/392; H01M 10/4207; H01M 10/482; H01M 10/486; H01M 2010/4278

(57) ABSTRACT

A method for monitoring the state of health of a battery with explosive cells including a plurality of internal components that are distributed throughout a plurality of regions (region 1, region 2), each region of the battery including at least one explosive cell, each internal component being associated with a device for checking the coherence of the internal component, the method including a first check for checking the coherence of the data of a first internal component in a region of the battery; a second check for checking the coherence of the data of a second internal component in the same region of the battery, the first and second checks being spaced apart by a predefined period of time.

### TECHNICAL FIELD OF THE INVENTION

The present invention relates to a method for monitoring state of health of a battery with explosive cells, such as a Li-ion or post-Li-ion battery. It also relates to a device for monitoring state of health of a battery implementing this method.

The invention finds applications in the field of batteries with explosive cells and, in particular, in the field of electric batteries intended for aeronautics.

### TECHNOLOGICAL BACKGROUND TO THE INVENTION

Lithium-ion, or Li-ion, batteries are explosive cells batteries, i.e. whose cells can thermally run away and explode. Indeed, a Li-ion battery includes several elements, called cells, the number of which varies according especially to the power of the battery. Each cell of a Lithium-Ion battery comprises a positive electrode (anode), a negative electrode (cathode) and an ion-conducting electrolyte enabling Lithium ions to migrate from the cathode to the anode when the battery is being charged, and from the anode to the cathode when it is being discharged.

By their very design, lithium-ion batteries can be dangerous because their cells are liable to explode as a result of thermal runaway, causing major damage. Indeed, thermal runaway can take the form of generation of gases, some of which are toxic, flames, smoke and even violent explosions. There are many possible causes of thermal runaway, such as overheating, electrical abuse, mechanical abuse, thermal abuse, vibration, etc. While some of these causes can be avoided by mastering handling and storage of Li-ion batteries, others, such as manufacturing defects, unfortunately cannot be controlled. Indeed, a defect, such as an impurity that enters a cell of the Li-ion battery upon manufacturing said battery, can generate resistance within the cell, originating a thermal runaway.

Given the design of these Li-ion batteries, the higher the power of a battery, the higher the risk of explosion and the greater the damage when the battery uncontrollably releases the energy stored.

In the field of aeronautics, batteries should be able to be installed on electric or hybrid aircraft. Batteries should therefore be high-power batteries. However, if a high-power battery suffers a thermal runaway, in particular when the aircraft is in flight, the consequences can be dramatic. Although most Li-ion batteries have built-in means of containing thermal runaway, thermal runaway cannot be contained for very long. It is therefore important that aircraft cockpit personnel can be warned of a risk of thermal runaway so that they can abort the flight and plan a safe landing as quickly as possible.

Solutions have been provided for monitoring thermal runaway. Several of these solutions have been described in document “A survey of methods for monitoring and detecting thermal runaway of lithium-ion batteries” by Z. Liao, S. Zhang, K. Li, G. Zhang and T. G. Habetler, Journal of Power Sources, Elsevier, 20/07/2019. Some of these solutions are based on algorithms that use data provided by sensors in the battery, such as voltage sensors, temperature sensors and current sensors. The drawback of this type of solution is that it is necessary to be sure that thermal runaway is actually occurring in order to avoid false positives; for this, it is appropriate to properly know and characterise thermal runaway. In addition, as there are an infinite number of thermal runaway scenarios, the algorithms generally incorporate all these scenarios, which leads to over-instrumenting the battery and increasing the mass and cost thereof.

Other solutions for monitoring thermal runaway have been provided, based on the addition of dedicated sensors such as pressure, gas or sound sensors, etc. The drawback of this type of solution is that the addition of sensors adds to the mass (due not only to the mass of the sensors but also to the volume occupied by the sensors, which implies a larger battery housing) and cost relating to the use of these sensors. In addition, this type of sensor requires an electronic board to analyse the signal sent back from the sensors, which further increases mass and cost of this solution.

There is therefore a real need for a means of monitoring state of health of a Li-ion battery in order to detect a potential thermal runaway within the battery, this means having to be simple to implement and easy to take on board an aircraft (i.e. with little or no added mass). Such a means is all the more necessary as an aeronautical safety standard requires at least two dissimilar means to be carried on board an aircraft to detect thermal runaway.

### SUMMARY OF THE INVENTION

To address the problems discussed above of complexity, mass and cost of the means of monitoring thermal runaway in a Li-ion battery, the applicant provides a method for monitoring state of health of an explosive cell battery using the internal components of the battery. In this method, it is considered that the absence of data provided by internal components being defective constitutes a source of information on the state of health of the battery cells.

According to a first aspect, the invention relates to a method for monitoring state of health of an explosive cell battery comprising a plurality of internal components distributed in a plurality of zones, each zone of the battery including at least one explosive cell, each internal component being associated with a means for checking consistency of said internal component, the method comprising at least:
a first consistency check for the data of a first internal component of a zone of the battery, and
a second consistency check for the data of a second internal component of the same zone of the battery, the first and second checks being spaced apart by at most a predefined time interval
   thermal runaway being detected when first non-consistent data are detected during the first consistency check and second non-consistent data are detected during the second consistency check.

This method makes it possible to monitor state of health of the battery using only the components already present in said battery, thereby not increasing mass and cost of the battery. The method is furthermore relatively simple to implement in that, outside the time window under consideration, it is independent of any thermal runaway scenario and any characterisation of the thermal runaway signature.

This method can be used for all kinds of high-power batteries whose cells are explosive. It can, of course, be implemented on Li-ion batteries or on batteries whose chemistry is still under development, known as post-Li-ion batteries.

Further to the characteristics just discussed in the previous paragraph, the method for monitoring state of health of a battery according to the invention may have one or more additional characteristics from among the following, considered individually or according to any technically possible combinations:
it includes:
   a plurality of first and second consistency checks, each combination of first and second consistency checks being carried out for a set of first and second internal components, of different natures; and
   detection of a potential thermal runaway when first and second non-consistent data are detected for a set of first and second internal components.
it includes confirming thermal runaway when at least a first and a second potential thermal runaway are detected, the first potential thermal runaway resulting from non-consistent data of a first set of first and second internal components of a same zone, the second potential thermal runaway resulting from non-consistent data of a second set of first and second internal components of the same zone.
the internal components of the battery comprise at least one data sensor positioned inside the battery cells and/or at least one data bus positioned in proximity to the battery cells.
the data sensors include voltage sensors and/or temperature sensors.
the time interval is of a predefined duration, ranging from a few minutes to a few tens of minutes.
a zone includes one cell or a set of several cells of the battery.
the number of internal components in a same zone of the battery is a parameter predefined as a function of the battery, this number being at least equal to two.

According to a second aspect, the invention relates to a device for monitoring state of health of an explosive cell battery, characterised in that it includes a battery management member, located outside the cells of the battery and implementing the method as previously defined.

This device has the advantage of being able to be implanted in an already existing member of the battery and, consequently, of not generating any additional mass.

Advantageously, the battery management member includes a thermal runaway determination unit receiving, as an input, data relating to the internal components and providing, as an output, thermal runaway information and a location for said thermal runaway.

### BRIEF DESCRIPTION OF THE FIGURES

Further advantages and characteristics of the invention will become apparent upon reading the following description, illustrated by the figures in which:

FIG. 1 represents, in the form of a function diagram, a general embodiment of the method for detecting thermal runaway according to the invention;

FIG. 2 represents, in the form of a function diagram, one example of the method according to the invention wherein the internal components include temperature sensors, voltage sensors and data buses whose losses are processed in parallel;

FIG. 3 represents, in schematic form, a thermal runaway determination unit according to the invention, integrated into the battery management member;

FIG. 4 schematically represents one example of implementation of the method of FIG. 2; and

FIG. 5 represents examples of time charts in a simulation of the method with a temperature sensor and a lost data bus.

### DETAILED DESCRIPTION

An exemplary embodiment of a method for monitoring state of health of a battery with explosive cells (or explosive cell battery) is described in detail hereinafter, with reference to the appended drawings. This example illustrates characteristics and advantages of the invention. However, it is reminded that the invention is not limited to this example.

In the figures, identical elements are marked with identical references. For reasons of legibility of the figures, size scales between the elements represented are not respected.

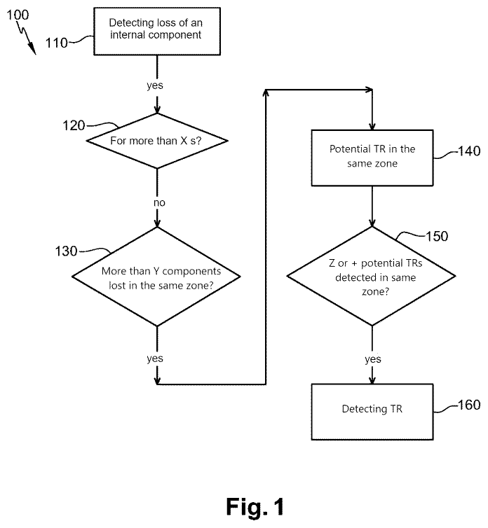

One example of a method 100 for monitoring state of health of an explosive cell battery is represented according to a general embodiment in FIG. 1. According to this method 100, the state of health of the battery is monitored by detecting presence of thermal runaway. A risk of thermal runaway is considered to exist when at least two internal components of the battery, which are located in a same zone of said battery, are considered to be “lost” during a same time window. An internal component is considered to be “lost” when the battery management member no longer receives data from this internal component. This loss of an internal component is detected by checking consistency of the internal component. Indeed, in the event of thermal runaway, the electrical power path is generally damaged; data from the internal component are then inconsistent; the loss of the internal component can be determined by reception of aberrant current values (for example, alternation between no current and other current values).

The loss of an internal component may be the consequence of several causes but, in the event of thermal runaway, many losses of internal components are detected in a reduced time window. This is because an explosive cell battery (more simply called a battery), such as a Li-ion battery, includes several cells, placed next to each other and connected to each other. Each cell is likely to undergo thermal runaway (referred to as TR in the figures), which generally spreads rapidly to the other cells. Each cell comprises a plurality of internal components, for example sensors and/or data buses. The sensors are connected to the battery management member via data buses, or communication buses; they thus provide the battery management member with various data, such as voltage, current, temperature, etc., via the data buses. A battery therefore comprises, by design, several so-called “internal” components distributed in zones in the battery, and the method of the invention takes account of this physical implementation of the sensors by defining detection zones related to this implementation. The battery zones may, for example, each be formed by a single cell or, on the contrary, by a set of cells.

In the method 100 of the invention, lost components for which the management member no longer receives data are detected and it is checked, on the one hand, whether these components have been lost during the same time window and, on the other hand, whether these lost components are positioned in a same zone of the battery. The method of the invention is based on the dynamics of thermal runaway and especially on the fact that thermal runaway destroys several internal components as it propagates. The method thus makes use of the fact that the loss of information from the internal components constitutes information on its own.

More precisely, and with reference to FIG. 1, the method includes the steps 110 to 160 set out below.

Step 110 is a lost component detection step. This step is performed by checking whether the data of the internal component are consistent. If the data of the internal component, which the battery management member receives, are non-consistent, i.e. if they are inconsistent or if they do not exist, then said management member considers that the internal component is lost. Indeed, in the event of thermal runaway, the internal component may:
either be completely destroyed and, in this case, the battery management member no longer receives any data from said internal component (the data are non-existent),
or be partially damaged, in which case the battery management member receives inconsistent data.

In step 120, the method determines whether this component has been lost for longer than a predefined time interval, also called a predefined time window. This time window, or time interval X, is defined in minutes or seconds depending, for example, on the number of cells in the battery and the size of these cells. This time window may be, for example, a few minutes or a few tens of minutes, according to the battery in question and/or its integration in the aircraft. Of course, the order of magnitude of the time window may vary according to the size of the batteries and/or their implementation. The time window makes it possible to check whether the loss of the component is potentially due to thermal runaway or rather to a one-off problem specific to this component, such as disconnection of the component or a defect in said component. Indeed, if a component has been lost outside this time window, for example one hour earlier whereas the time window is a few minutes, this means that the component has suffered a one-off problem; in the case of thermal runaway, the propagation of thermal runaway is rapid and several components are quickly destroyed following one another. Step 120 checks that the loss of the component is recent. If the loss occurred before the time window, the method does not proceed. On the other hand, if the loss of this component is recent and occurred during the time window, then the method proceeds to step 130.

In step 130, the method checks whether more than Y components, lost during this time window, are located in the same zone of the battery. The threshold number Y of lost components is a predefined number, determined as a function especially of the number of internal components and the number of cells of the battery. If this is the case, i.e. if more than Y lost components come from the same zone, then the method considers, in step 140, that there is a potential thermal runaway in this zone. Otherwise, the method does not proceed.

The method then checks, in step 150, whether a threshold number Z of potential thermal runaway events has been detected in the same zone. Indeed, as explained previously, a thermal runaway in one zone of the battery spreads very quickly to the other zones. Therefore, if less than the threshold number Z of potential thermal runaway events is detected, it is not considered to be actual thermal runaway. On the contrary, if several potential thermal runaway events are detected in step 150, then it is considered that thermal runaway is occurring in the battery (step 160). When it has detected existence of thermal runaway, the battery management member transmits necessary information to the aircraft cockpit and/or controls emergency operations provided for in the event of thermal runaway.

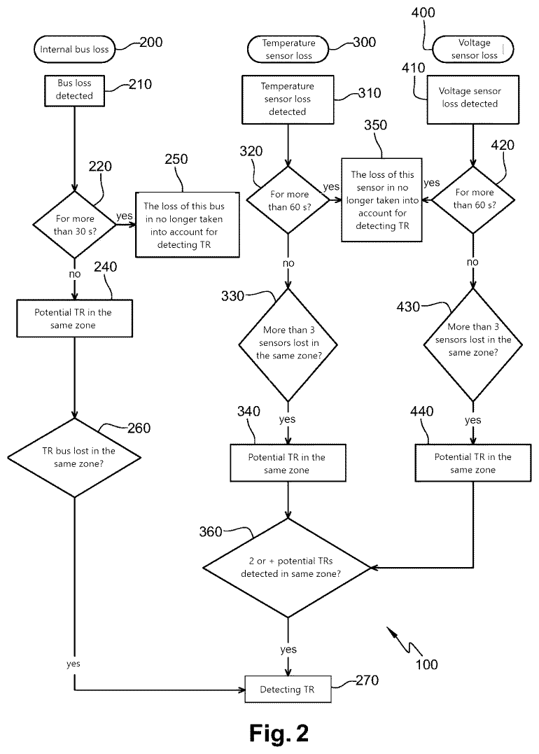

The method according to FIG. 1 is a general method wherein all the internal components of the battery are processed in a similar way. In another embodiment, represented in FIG. 2, the nature of the components is taken into consideration. For example, data buses are treated separately from sensors such as voltage sensors and temperature sensors. In the example of FIG. 2, where each zone of the battery includes both voltage sensors and temperature sensors, the method processes the loss of a voltage sensor (processing 400) and the loss of a temperature sensor (processing 300) in parallel. The method also processes the loss of a data bus (processing 200) in parallel because a lot of data passes through a same data bus, especially data from temperature sensors and data from voltage sensors. The loss of a data bus is treated differently to the loss of a sensor because the sensor data pass through the data bus; therefore, if a data bus has an one-off problem (such as a disconnection), this results in an absence of data from both the sensor and the data bus; to avoid “false positives”, i.e. to avoid an one-off problem with a data bus being detected as thermal runaway, the loss of a data bus is treated differently to the loss of a sensor in the method of FIG. 2.

The diagram of FIG. 2 shows an example of the method 100 of the invention in the case where each zone of the battery includes voltage sensors and temperature sensors each connected, via data buses, to the battery management member. Of course, other types of sensors, such as current sensors, could be taken into consideration in the method of the invention, instead of or in addition to the voltage and temperature sensors, processing of the loss of these sensors being identical to the processing operations 300 and 400 described in connection with FIG. 2.

In the example of FIG. 2, the method checks in step 410 whether a voltage sensor has been lost. This step 410 is identical to step 110 of method 100, except that it is applied to the voltage sensors. If a voltage sensor is detected as lost, in step 410, then the method checks (step 420) whether this loss has occurred during the time window X. Step 420 for the voltage sensor is identical to step 120 in FIG. 1. If loss of the voltage sensor occurred earlier than the time window, then the loss of this sensor is not taken into account for thermal runaway detection (step 350). On the other hand, if loss of the voltage sensor occurred during the time window X, then processing 400 continues with a step 430 of checking number of voltage sensors lost in the same zone. If the number of voltage sensors lost in the same zone is greater than the threshold number Y, with Y for example equal to 3, then it is considered that there is a potential thermal runaway in the zone (step 440).

Processing 300 of the loss of a temperature sensor is identical to processing 400 of the loss of a voltage sensor. Thus, it is checked in step 310 whether a temperature sensor is lost (this step 310 is identical to step 110 of method 100, except that it is applied to temperature sensors). If a temperature sensor is detected as lost, in step 310, then the method checks in step 320 whether this loss has occurred during the time window X. Step 320 for the temperature sensor is identical to step 120 in FIG. 1. If the loss of the temperature sensor occurred earlier than the time window, then the loss of this sensor is not taken into account for thermal runaway detection (step 350). On the other hand, if the loss of the temperature sensor occurred during the time window, then processing 300 continues with a step 330 of checking number of temperature sensors lost in the same zone. If the number of temperature sensors lost in the same zone is greater than the threshold number Y, with Y for example equal to 3, then it is considered that there is a potential thermal runaway in the zone (step 340).

The method then includes a step 360 during which it is checked whether potential thermal runaway events have been detected in the same zone, for the voltage sensors and for the temperature sensors. This step 360 corresponds to step 150 in FIG. 1 if the threshold number Y is equal to 2. Indeed, if thermal runaway occurs in a zone of the battery, then several internal components (voltage sensors, temperature sensors, etc.) have been destroyed. In step 360, it is determined whether at least two potential thermal runaway events have been detected; if so, the method proceeds to step 270 described later.

In parallel with processing operations 300 and 400, the method performs processing 200 for the loss of a data bus. Processing 200 for the loss of a data bus consists, when a data bus is detected as lost in step 210, in checking in step 220 whether this loss occurred during the time window X. Step 220 for the data bus is identical to steps 320 and 420 for the loss of a sensor. If the loss of the data bus occurred earlier than the time window X, then the loss of this data bus is not taken into account for thermal runaway detection (step 250). On the contrary, if the loss of the data bus occurred during the time window X, then it is considered that there is a potential thermal runaway in the zone (step 240).

Processing 200 continues with a step 260 of checking the number of data buses lost in the same zone. If two data buses are detected as lost in the same zone and if it has been determined in step 360 that several potential thermal runaway events have been detected in the same zone by processing operations 300 and 400, then it is considered that thermal runaway is occurring in the battery (step 270). When it has detected existence of a thermal runaway, the battery management member transmits necessary information to the aircraft cockpit and/or controls emergency operations provided for in the event of thermal runaway.

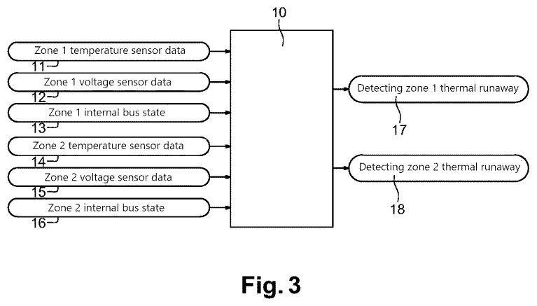

FIG. 3 represents, in functional form, an example of the function to be integrated into the battery management member, located outside the battery cells. This battery management member may, for example, be a BMS (Battery Management System) incorporating a unit 10 for determining thermal runaway, comprising, for example, an electronic processing card. In the example method of FIG. 2, the thermal runaway determination unit 10 receives, as an input, data from the temperature sensors, data from the voltage sensors and the state of the data buses and provides, as an output, thermal runaway detection information and information about the location of said thermal runaway. In particular, in the example of FIG. 3, the thermal runaway determination unit 10:
receives, as an input, data from the temperature sensors 11 in zone 1 of the battery, data from the voltage sensors 12 in zone 1 and the state of the data buses 13 in zone 1, data from the temperature sensors 14 in zone 2 of the battery, data from the voltage sensors 15 in zone 2 and the state of the data buses 16 in zone 2; and
provides, as an output, information 17 of detecting thermal runaway in zone 1 and information 18 of detecting thermal runaway in zone 2.

Of course, the unit 10 receives data from all the sensors and data buses whose loss the method wishes to detect, whatever the type of sensors, the type of buses and the zones of the battery, and provides thermal runaway detection information for all the zones of the battery.

In some embodiments, the thermal runaway detection function can be implanted in a management member other than the BMS. It can be integrated into any battery processing unit through which measurements pass (for example an LTC 6804 battery monitor, etc.).

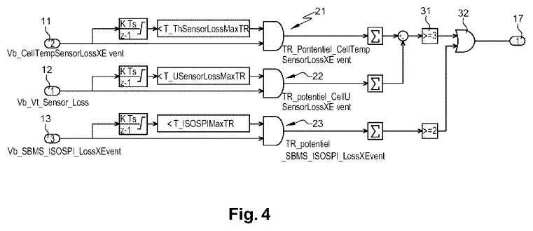

An example implementation of the thermal runaway detection function according to the invention is represented in FIG. 4, in conjunction with FIG. 3. The example implementation in FIG. 4 shows, for zone 1 of the battery, the input receiving data from the temperature sensors 11, the input receiving data from the voltage sensors 12 and the input receiving the status of the data buses 13. FIG. 4 also shows:
processing line 21 for the loss of the temperature sensors 11 (which corresponds to steps 310 to 340 of the method of FIG. 2),
processing line 22 for the loss of voltage sensors 12 (corresponding to steps 410 to 440 of the method of FIG. 2),
processing line 23 for the loss of data bus 13 (corresponding to steps 210 to 260 of the method of FIG. 2),
the test 31 of determining the number of potential thermal runaway events of the sensors (which corresponds to step 360 of the method of FIG. 2), and
determination 32 of a thermal runaway in zone 1 (corresponding to step 270 of the method of FIG. 2).

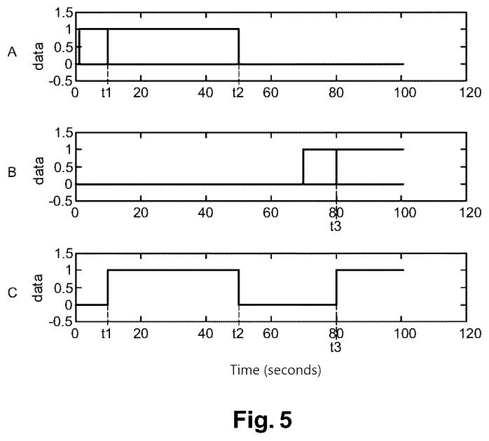

FIG. 5 represents examples of time charts of a simulated loss of a temperature sensor (curve A), a simulated loss of a data bus (curve B) and the resultant of curves A and B, after application of method 100 (curve C). In curves A and B, the signal changes to 1 when a sensor/bus loss is detected. In the example:
just after time instant t0 (i.e. at to plus a few tenths or hundredths of a second), the signal changes to 1 on curve A: the loss of a first sensor is detected;
at time instant t1, the signal remained to 1 on curve A means that the loss of a second sensor has been detected; the signal on curve C then changes to 1: thermal runaway is detected;
at time instant t2, the signal on curve A changes to 0: sensor loss detection (curve A) and thermal runaway detection (curve C) are reset;
between time instants t2 and t3, the curve B signal changes to 1: the loss of a communication bus is detected;

at time instant t3, the signal from curve B remains to 1: the loss of a second communication bus is detected; the signal from curve C then changes to 1: thermal runaway is detected.

The method just described not only makes it possible to detect thermal runaway using only the components already incorporated in the battery, i.e. without adding any new components, but it also makes it possible to determine the thermal runaway zone. Moreover, this method is applicable regardless of the type of cells in the battery since the only information used is that relating to data loss.

Although described through a number of examples, alternatives and embodiments, the method for detecting thermal runaway according to the invention, and its implementation device, comprise various alternatives, modifications and improvements which will be obvious to the person skilled in the art, it being understood that these alternatives, modifications and improvements are within the scope of the invention.

1. A method for monitoring state of health of an explosive cell battery including a plurality of internal components distributed in a plurality of zones, each zone of the battery including at least one explosive cell, each internal component being associated with a means for checking consistency of said internal component, the method comprising:
a first consistency check for data of a first internal component of a zone of the battery, and
a second consistency check for data of a second internal component of the same zone of the battery, the first and second checks being spaced apart by at most a predefined time interval,
thermal runaway being detected when first non-consistent data are detected during the first consistency check and second non-consistent data are detected during the second consistency check.

2. The method according to claim 1, comprising:
a plurality of first and second consistency checks, each combination of first and second consistency checks being performed for a set of first and second internal components, of different natures; and
detection of a potential thermal runaway when first and second non-consistent data are detected for a set of first and second internal components.

3. The method according to claims 2, comprising confirming thermal runaway when at least a first and a second potential thermal runaway events are detected, the first potential thermal runaway resulting from non-consistent data of a first set of first and second internal components of a same zone, the second potential thermal runaway resulting from non-consistent data of a second set of first and second internal components of the same zone.

4. The method according to claim 1, wherein the internal components of the battery comprise at least one data sensor positioned inside the battery cells and/or at least one data bus positioned in proximity to the battery cells.

5. The method according to claim 4, wherein the at least one data sensor includes a voltage sensor and/or a temperature sensor.

6. The method according to claim 1, wherein the time interval is of a predefined duration, ranging from a few minutes to a few tens of minutes.

7. The method according to claim 1, wherein a zone of the plurality of zones includes a cell or a set of several cells of the battery.

8. The method according to claim 1, wherein a number of internal components in a same zone of the battery is a parameter predefined as a function of the battery, said number being at least equal to two.

9. A device for monitoring state of health of an explosive cell battery, comprising a battery management member, located outside the cells of the battery and implementing the method according to claim 1.

10. The device according to claim 9, wherein the battery management member includes a thermal runaway determination unit receiving, as an input, data relating to the internal components and providing, as an output, thermal runaway information and location of said thermal runaway.
